(19) United States
(12) Patent Application Publication
(10) Pub. No.: US 2025/0291971 A1
(43) Pub. Date: Sep. 18, 2025

(54) METHOD FOR QUANTITATIVELY ESTIMATING POTASSIUM DEMAND OF REGIONAL CORN PLANTS DURING KEY GROWTH STAGES

(71) Applicant: JILIN UNIVERSITY, Changchun City (CN)

(72) Inventors: Shengbo CHEN, Changchun City (CN); Xinwei ZHAO, Changchun City (CN); Bingxue ZHU, Changchun City (CN); Yafeng YU, Changchun City (CN); Peng LU, Changchun City (CN)

(21) Appl. No.: 18/824,130

(22) Filed: Sep. 4, 2024

(30) Foreign Application Priority Data
Mar. 18, 2024 (CN) 202410306087.9

(51) Int. Cl. G06F 30/20

(52) U.S. Cl. CPC G06F 30/20

(57) ABSTRACT

Provided is a method for quantitatively estimating potassium demand of regional corn plants during key growth stages. The method includes: S1: calculating critical potassium concentration values Kc for each growth stage of corn; S2: calculating potassium nutrition indexes (KNIs) for each growth stage of the corn; S3: constructing KNI inversion models for each growth stage of the corn; S4: obtaining leaf area index (LAI) data of the corn and calculating above-ground biomass W for each growth stage of the corn; S5: calculating potassium fertilizer utilization rates KAE for each growth stage of the corn based on above-ground potassium accumulations in each growth stage of the corn; S6: calculating relative dry biomass RDW for each growth stage of the corn, and optimal KNI values, denoted as KNItarget, for each growth stage of the corn; and S7: obtaining a plant potassium content absorption model Kabs for each growth stage of the corn.

### CROSS REFERENCE TO RELATED APPLICATION

This patent application claims the benefit and priority of Chinese Patent Application No. 2024103060879, filed with the China National Intellectual Property Administration on Mar. 18, 2024, the disclosure of which is incorporated by reference herein in its entirety as part of the present application.

### TECHNICAL FIELD

The present disclosure relates to the technical field of crop nutrition diagnosis, and in particular, to a method for quantitatively estimating potassium demand of regional corn plants during key growth stages.

### BACKGROUND

Corn is one of the important crops in China, rich in various nutrients such as glutathione, carotenoids, and vitamin E. It exhibits strong drought resistance, cold resistance, and adaptability to poor soil conditions and various environments, making it a vital feed source in livestock, farming, aquaculture, and other fields, and also an indispensable raw material in industries such as food, healthcare, light industry, and chemical industry. Therefore, diagnosing the nutritional performance of corn during its growth period is crucial. In the diagnosis of nutritional performance of corn, potassium demand during key growth stages of the plants is obtained to provide guidance for precise potassium fertilizer management, which is significant for reducing potassium fertilizer application and promoting sustainable agricultural development.

Traditional methods for calculating the potassium demand during the key growth stages of corn require destructive sampling in the field, followed by chemical analysis of crop concentration and biomass information in the laboratory. This method is costly, time-consuming, and difficult to be put into regional applications to obtain large-scale nutritional status data, and also complicates fertilization guidance and soil pollution exploration. Meanwhile, remote sensing, as a novel approach, can acquire surface information about crop plants, reflecting nutritional deficiency status of the crop plants. However, current remote sensing methods primarily provide qualitative assessments of plant nutrition levels and cannot achieve quantitative evaluations necessary for fertilization guidance.

In summary, there is an urgent need to develop a method that is cost-effective, time-efficient, and capable of quantitatively estimating potassium demand of regional corn plants during key growth stages.

### SUMMARY

To address the above issues, the present disclosure provides a method for quantitatively estimating potassium demand of regional corn plants during key growth stages, which can enhance the timeliness of potassium nutrition diagnosis in corn, has high universality, and can provide guidance for precise potassium fertilizer management.

The method for quantitatively estimating potassium demand of regional corn plants during key growth stages provided by the present disclosure specifically includes the following steps:
S1: calculating critical potassium concentration values Kc for five growth stages of corn, including a jointing stage, a silking stage, a filling stage, a milk stage, and a maturity stage; S2: calculating potassium nutrition indexes (KNIs) for each growth stage of the corn;
S3: calculating a vegetation index of the corn and constructing KNI inversion models for the jointing stage, the silking stage, the filling stage, the milk stage, and the maturity stage of the corn based on the vegetation index;
S4: obtaining leaf area index (LAI) data of the corn and calculating corresponding above-ground biomass W for the five growth stages: the jointing stage, the silking stage, the filling stage, the milk stage, and the maturity stage;
S5: calculating potassium fertilizer utilization rates KAE for each growth stage of the corn based on above-ground potassium accumulations in each growth stage of the corn;
S6: calculating relative dry biomass RDW for each growth stage of the corn, where the KNI is considered to be optimal, denoted as KNItarget, when the relative dry biomass RDW is equal to 1; and determining KNItarget for each growth stage of the corn; and
S7: obtaining a plant potassium content absorption model Kabs for each growth stage of the corn based on the critical potassium concentration values Kc, actual potassium concentration values Kact, the above-ground biomass W, KNItarget, and the potassium fertilizer utilization rates KAE for each growth stage of the corn.

Further, the plant potassium content absorption model Kabs for each growth stage of the corn in S7 is calculated using the following formula:

$${K}_{abs} = \frac{{WK}_{c} ( {KNI}_{target} - KNI )}{KAE}$$

Further, in S6, KNItarget for each growth stage of the corn is determined in the following manner: non-linearly fitting the relative dry biomass RDW with the KNIs for each growth stage of the corn to obtain fitting curves for each growth stage of the corn, and then substituting the relative dry biomass RDW=1 into the fitting curves for each growth stage of the corn to obtain KNI values for each growth stage of the corn, where the calculated KNI values are KNItarget values for each growth stage of the corn.

Further, the fitting curves for each growth stage of the corn are as follows:

$$jointing stage : RDW = - 3.009 {e}^{( - KNI / 0.448 )} + 1.147 ;$$

$$silking stage : RDW = - 10.848 {e}^{( - KNI / 0.257 )} + 1.126 ;$$

$$filling stage : RDW = - 27.795 {e}^{( - KNI / 0.196 )} + 1.113 ;$$

$$milk stage : RDW = - 13.099 {e}^{( - KNI / 0.185 )} + 1.095 ;$$

$$maturity stage : RDW = - 7.553 {e}^{( - KNI / 0.165 )} + 1.049 ;$$

where e is a natural constant, an infinite non-repeating decimal, which can be approximated as 2.71828; when RDW in the fitting curves for each growth stage of the corn is set to 1, the KNI values from the fitting curves for each growth stage are the KNItarget values for each growth stage of the corn.

Further, in S4, the above-ground biomass W corresponding to the jointing stage, the silking stage, the filling stage, the milk stage, and the maturity stage of the corn is calculated using the following formulas:

jointing stage: W=2.852LAI^{0.985};

silking stage: W=5.317LAI^{0.487};

filling stage: W=6.525LAI^{0.373};

milk stage: W=7.645LAI^{0.347};

maturity stage: W=9.680LAI^{0.361.}

Further, in S3, spectral data and remote sensing data of the corn are acquired first. The vegetation index of the corn is calculated based on a spectral response function of the acquired spectral data and remote sensing data, where the KNI for the jointing stage shows a high correlation with a soil-adjusted vegetation index (SAVI); the KNI for the silking stage and the KNI for the filling stage show a high correlation with a green normalized difference vegetation index (GNDVI); the KNI for the milk stage and the KNI for the maturity stage have a high correlation with a normalized difference vegetation index (NDVI).

Further, the KNI inversion models constructed in S3 for the jointing stage, the silking stage, the filling stage, the milk stage, and the maturity stage of the corn are as follows:

$$jointing stage : KNI = 7.264 SAVI - 5.142 ;$$

$$silking stage : KNI = 19.555 GNDVI - 14.606 ;$$

$$filling stage : KNI = 14.005 GNDVI - 9.836 ;$$

$$milk stage : KNI = 21.723 NDVI - 18.415 ;$$

$$maturity stage : KNI = 10.132 NDVI - 7.139 .$$

Compared with the prior art, the present disclosure has the following beneficial effects:

1. The present disclosure establishes a model between corn potassium demand and the potassium nutrition index in corn, transforming the complex calculation of potassium demand into the acquisition of the potassium nutrition index, thereby significantly increasing the timeliness of potassium nutrition diagnosis in corn.

2. By analyzing the relationship between key indicators and corn biomass, the present disclosure constructs a plant potassium content absorption model, which not only achieves a high level of accuracy but also takes into consideration the differences in growth periods and potassium fertilizer utilization rates specific to planting regions of corn, demonstrating high versatility.

3. Based on field experiment data, by acquiring critical indicators for potassium nutrition diagnosis in plants, the present disclosure designs remote sensing inversion models for the critical indicators, facilitating the realization of potassium nutrition diagnosis in corn plants. This provides guidance for precise potassium fertilizer management, holding significant practical implications for reducing potassium fertilizer application and promoting sustainable agricultural development.

### DETAILED DESCRIPTION OF THE EMBODIMENTS

To make the objective, technical solutions and advantages of the present disclosure clearer and more comprehensible, the present disclosure will be further described below in detail in conjunction with embodiments. It should be understood that the specific embodiments described herein are merely intended to explain the present disclosure, but not to limit the present disclosure.

A method for quantitatively estimating potassium demand of regional corn plants during key growth stages includes the following steps:

S1: Calculate critical potassium concentration values Kc for five growth stages of corn, including a jointing stage, a silking stage, a filling stage, a milk stage, and a maturity stage.

Variance analysis is conducted on acquired above-ground biomass and potassium concentration data for the five growth stages of the corn: the jointing stage, the silking stage, the filling stage, the milk stage, and the maturity stage, to identify potassium sufficiency points and potassium deficiency points. A potassium deficiency point is defined as a point where the biomass shows a significant increase influenced by fertilization, while biomass of a potassium sufficiency point shows no significant increase. Then, using the biomass at the potassium deficiency points within the same growth stage as the x-coordinates and the corresponding potassium concentrations as the y-coordinates, linear fitting is performed to obtain a straight line. By using average biomass of the potassium sufficiency points as maximum biomass, a vertical line is drawn on the fitted line graph with the maximum biomass as the x-coordinate. The intersection point of the vertical line indicates a minimum potassium concentration required for achieving maximum growth in the current growth stage, known as the critical potassium concentration point, thus determining the critical potassium concentration values Kc for the five growth stages. A curve model for Kc is as follows:

$${K}_{c} = {aW}^{- b}$$

where Kc (g/kg) denotes a critical potassium concentration, W(t/hm²) denotes maximum above-ground biomass of the corn, parameter a denotes a plant critical potassium concentration when the above-ground biomass reaches 1 t/hm², and parameter b denotes a statistical parameter determining the slope of a critical potassium concentration dilution curve.

S2: Calculate potassium nutrition indexes (KNIs) for each growth stage of the corn using a KNI formula as follows:

$$KNI = \frac{{K}_{act}}{{K}_{c}}$$

where Kact denotes an actual potassium concentration value, Kc denotes a critical potassium concentration value, and the KNI is a ratio of the two. When the KNI is equal to 1, the potassium nutrition of a corn plant is in an ideal state. When the KNI is greater than 1, the potassium nutrition of the corn plant is excessive, indicating that there is no need to continue adding potassium fertilizer. When the KNI is less than 1, the potassium nutrition of the corn plant is insufficient, necessitating additional application of potassium fertilizer.

S3: Calculate a vegetation index of the corn and construct KNI inversion models for the jointing stage, the silking stage, the filling stage, the milk stage, and the maturity stage of the corn based on the vegetation index.

Spectral data and remote sensing data of the corn are acquired first. The vegetation index of the corn is calculated based on a spectral response function of the acquired spectral data and remote sensing data, showing that KNIs of different growth stages have different correlations with different vegetation indexes, where the KNI for the jointing stage shows a high correlation with a soil-adjusted vegetation index (SAVI); the KNI for the silking stage and the KNI for the filling stage show a high correlation with a green normalized difference vegetation index (GNDVI); the KNI for the milk stage and the KNI for the maturity stage have a high correlation with a normalized difference vegetation index (NDVI).

Spectral reflectance data indicates that when a light source illuminates the surface of an object, the object selectively reflects electromagnetic waves of different wavelengths. Spectral reflectance refers to a ratio of the light flux reflected by an object in a specific wavelength band to the light flux incident on the object. The spectral reflectance is an inherent property of the surface of the object, and is a characterization of color by the object. It not only comprehensively records color information of the object, but also serves as a representation of the surface material of the object.

Formulas for SAVI, GNDVI, and NDVI are as follows:

| | |
|---|---|
| Soil-adjusted VI (SAVI) | 1.5 (NIR − R)/(NIR + R + 0.5) |
| Green normalized difference | (NIR − G)/(NIR + G) |
| VI (GNDVI) | |
| Normalized difference VI (NDVI) | (NIR − R)/(NIR + R) |

SAVI stands for soil-adjusted vegetation index, where NIR and R represent the near-infrared and red bands of remote sensing data, respectively.
GNDVI stands for green normalized difference vegetation index, where NIR and G represent the near-infrared and green bands of remote sensing data, respectively.
NDVI stands for normalized difference vegetation index, where NIR and R represent the near-infrared and red bands of remote sensing data, respectively.

The KNI inversion models constructed in S3 for the jointing stage, the silking stage, the filling stage, the milk stage, and the maturity stage of the corn are as follows:

$$jointing stage : KNI = 7.264 SAVI - 5.142 ;$$

$$silking stage : KNI = 19.555 GNDVI - 14.606 ;$$

$$filling stage : KNI = 14.005 GNDVI - 9.836 ;$$

$$milk stage : KNI = 21.723 NDVI - 18.415 ;$$

$$maturity stage : KNI = 10.132 NDVI - 7.139 .$$

S4: Obtain leaf area index (LAI) data of the corn, establish relationships between above-ground biomass W and LAI for the jointing stage, the silking stage, the filling stage, the milk stage, and the maturity stage of the corn, and calculate corresponding above-ground biomass W for the jointing stage, the silking stage, the filling stage, the milk stage, and the maturity stage of the corn.

The above-ground biomass W corresponding to each growth stage is calculated using the following formulas:

jointing stage: W=2.852LAI^{0.985};

silking stage: W=5.317LAI^{0.487};

filling stage: W=6.525LAI^{0.373};

milk stage: W=7.645LAI^{0.347};

maturity stage: W=9.680LAI^{0.361};

S5: Calculate potassium fertilizer utilization rates KAE for each growth stage of the corn based on above-ground potassium accumulations in each growth stage of the corn. Specifically,

Above-ground potassium accumulation of plants=dry natter of the plants×potassium content in the dry matter of the plants;

Potassium fertilizer utilization rate KAE=(above-ground potassium accumulation of plants in fertilized area−above-ground potassium accumulation of plants in control area)/amount of potassium applied×100%.

S6: Calculate relative dry biomass RDW for each growth stage of the corn using a relative dry biomass formula as follows:

Relative dry biomass RDW=above-ground biomass/maximum above-ground biomass at the same growth stage.

The KNI is considered to be optimal, denoted as KNItarget, when the relative dry biomass RDW is equal to 1, and KNItarget for each growth stage of the corn is determined. KNItarget for each growth stage of the corn is determined in the following manner: non-linearly fitting the relative dry biomass RDW with the KNIs for each growth stage of the corn to obtain fitting curves for each growth stage of the corn, and then substituting the relative dry biomass RDW=1 into the fitting curves for each growth stage of the corn to obtain KNI values for each growth stage of the corn, where the calculated KNI values are KNItarget values for each growth stage of the corn.

The fitting curves for each growth stage of the corn are as follows:

$$jointing stage : RDW = - 3.009 {e}^{( - KNI / 0.448 )} + 1.147 ;$$

$$silking stage : RDW = - 10.848 {e}^{( - KNI / 0.257 )} + 1.126 ;$$

$$filling stage : RDW = - 27.795 {e}^{( - KNI / 0.196 )} + 1.113 ;$$

$$milk stage : RDW = - 13.099 {e}^{( - KNI / 0.185 )} + 1.095 ;$$

$$maturity stage : RDW = - 7.553 {e}^{( - KNI / 0.165 )} + 1.049 ;$$

where e is a natural constant, an infinite non-repeating decimal, which can be approximated as 2.71828; when RDW in the fitting curves for each growth stage of the corn is set to 1, the KNI values from the fitting curves for each growth stage are the KNItarget values for each growth stage of the corn.

S7: Obtain a plant potassium content absorption model Kabs for each growth stage of the corn based on the critical potassium concentration values Kc, actual potassium concentration values Kact, the above-ground biomass W, KNItarget, and the potassium fertilizer utilization rates KAE for each growth stage of the corn.

The plant potassium content absorption model Kabs for each growth stage of the corn is calculated using the following formula:

$${K}_{abs} = \frac{{WK}_{c} ( {KNI}_{target} - KNI )}{KAE} .$$

Although the embodiments of the present disclosure are shown and described above, it can be understood that, the foregoing embodiments are examples, and cannot be construed as a limitation to the present disclosure. Within the scope of the present disclosure, a person of ordinary skill in the art may make changes, modifications, replacement, and variations to the foregoing embodiments.

The foregoing embodiments of the present disclosure are not intended to limit the protection scope of the present disclosure. Any changes and modifications made according to the technical idea of the present disclosure shall fall within the protection scope of the claims of the present disclosure.

1. A method for quantitatively estimating potassium demand of regional corn plants during key growth stages, comprising the following steps:
establishing a fertilization control system comprising a processor, which is configured for:
S1: calculating, critical potassium concentration values Kc for five growth stages of corn as a first coefficient of a plant potassium content absorption model Kabs, the five growth stages of corn comprising a jointing stage, a silking stage, a filling stage, a milk stage, and a maturity stage;
wherein a curve model of the critical potassium concentration values Kc corresponding to the five growth stages is as follows:
Kc=aW−b;
wherein Kc (g/kg) denotes a critical potassium concentration, W(t/hm²) denotes maximum above-ground biomass of the corn, parameter a denotes a plant critical potassium concentration when the above-ground biomass reaches 1t/hm², and parameter b denotes a statistical parameter determining a slope of a critical potassium concentration dilution curve;
S2: calculating potassium nutrition indexes (KNIs) for each growth stage of the corn, wherein the KNIs for each growth stage of the corn is calculated using a KNI formula as follows:
$$KNI = \frac{{K}_{act}}{{K}_{c}} ;$$
wherein Kact denotes an actual potassium concentration value, Kc denotes a critical potassium concentration value, and the KNI is a ratio of the actual potassium concentration value to the critical potassium concentration value; when the KNI is equal to 1, potassium nutrition of a corn plant is in an ideal state; when the KNI is greater than 1, the potassium nutrition of the corn plant is excessive, indicating that there is no need to continue adding potassium fertilizer; and when the KNI is less than 1, the potassium nutrition of the corn plant is insufficient, necessitating additional application of potassium fertilizer;
S3: calculating a vegetation index of the corn and constructing KNI inversion models for the jointing stage, the silking stage, the filling stage, the milk stage, and the maturity stage of the corn based on the vegetation index;
S4: obtaining, for the target region, leaf area index (LAI) data of the corn and calculating corresponding above-ground biomass W for the five growth stages of the jointing stage, the silking stage, the filling stage, the milk stage, and the maturity stage;
S5: calculating potassium fertilizer utilization rates KAE for each growth stage of the corn based on above-ground potassium accumulations in each growth stage of the corn, as a second coefficient of the plant potassium content absorption model Kabs;
S6: calculating relative dry biomass RDW for each growth stage of the corn, wherein the KNI is considered to be optimal, denoted as KNItarget, when the relative dry biomass RDW is equal to 1; and determining an optimal potassium nutrition index KNItarget for each growth stage of the corn, a third coefficient of the plant potassium content absorption model Kabs; and
S7: obtaining the plant potassium content absorption model Kabs for each growth stage of the corn based on the critical potassium concentration values Kc, actual potassium concentration values Kact, the above-ground biomass W, the optimal potassium nutrition index KNItarget, and the potassium fertilizer utilization rates KAE for each growth stage of the corn;
wherein a formula for calculating the plant potassium content absorption model Kabs for each growth stage of the corn in S7 is as follows:
$${K}_{abs} = \frac{{WK}_{c} ( {KNI}_{target} - KNI )}{KAE}$$
S8: determining fertilization amount of the potassium fertilizer for each growth stage of the corn based on the plant potassium content absorption model Kabs;
receiving spectral data and remote sensing data of target corn in a target area at a current growth stage, to obtain a vegetation index and LAI data of the target corn at the current growth stage from the spectral data and remote sensing data;
Inputting the vegetation index and the LAI data of the target corn at the current growth stage into the fertilization control system, to obtain a fertilization amount of the potassium fertilizer of the target corn at the current growth stage; and
sending a signal indicating the fertilization amount of the potassium fertilizer of the target corn at the current growth stage to a fertilization machinery for applying potassium fertilizer with the fertilization amount of the potassium fertilizer to the target corn.

2. The method for quantitatively estimating potassium demand of regional corn plants during key growth stages according to claim 1, wherein in S6, KNItarget for each growth stage of the corn is determined in the following manner: non-linearly fitting the relative dry biomass RDW with the KNIs for each growth stage of the corn to obtain fitting curves for each growth stage of the corn, and then substituting the relative dry biomass RDW=1 into the fitting curves for each growth stage of the corn to obtain KNI values for each growth stage of the corn, wherein the calculated KNI values are KNItarget values for each growth stage of the corn.

3. The method for quantitatively estimating potassium demand of regional corn plants during key growth stages according to claim 2, wherein the fitting curves for each growth stage of the corn are as follows:
$$the jointing stage : RDW = - 3.009 {e}^{( - KNI / 0.448 )} + 1.147 ;$$
$$the silking stage : RDW = - 10.848 {e}^{( - KNI / 0.257 )} + 1.126 ;$$
$$the filling stage : RDW = - 27.795 {e}^{( - KNI / 0.196 )} + 1.113 ;$$
$$the milk stage : RDW = - 13.099 {e}^{( - KNI / 0.185 )} + 1.095 ;$$
$$the maturity stage : RDW = - 7.553 {e}^{( - KNI / 0.165 )} + 1.049 ;$$
wherein e is a natural constant, an infinite non-repeating decimal, which can be approximated as 2.71828; when RDW in the fitting curves for each growth stage of the corn is set to 1, the KNI values from the fitting curves for each growth stage are the KNItarget values for each growth stage of the corn.

4. The method for quantitatively estimating potassium demand of regional corn plants during key growth stages according to claim 3, wherein in S4, the above-ground biomass W corresponding to the jointing stage, the silking stage, the filling stage, the milk stage, and the maturity stage of the corn is calculated using the following formulas:
the jointing stage: W=2.852LAI^{0.985};
the silking stage: W=5.317LAI^{0.487};
the filling stage: W=6.525LAI^{0.373};
the milk stage: W=7.645LAI^{0.347};
the maturity stage: W=9.680LAI^{0.361}.

5. The method for quantitatively estimating potassium demand of regional corn plants during key growth stages according to claim 4, wherein in S3, spectral data and remote sensing data of the corn are acquired first; the vegetation index of the corn is calculated based on a spectral response function of the acquired spectral data and remote sensing data, wherein the KNI for the jointing stage shows a high correlation with a soil-adjusted vegetation index (SAVI); the KNI for the silking stage and the KNI for the filling stage show a high correlation with a green normalized difference vegetation index (GNDVI); the KNI for the milk stage and the KNI for the maturity stage have a high correlation with a normalized difference vegetation index (NDVI).

6. The method for quantitatively estimating potassium demand of regional corn plants during key growth stages according to claim 5, wherein the KNI inversion models constructed in S3 for the jointing stage, the silking stage, the filling stage, the milk stage, and the maturity stage of the corn are as follows:
$$the jointing stage : KNI = 7.264 SAVI - 5.142 ;$$
$$the silking stage : KNI = 19.555 GNDVI - 14.606 ;$$
$$the filling stage : KNI = 14.005 GNDVI - 9.836 ;$$
$$the milk stage : KNI = 21.723 NDVI - 18.415 ;$$
$$the maturity stage : KNI = 10.132 NDVI - 7.139 .$$
